(19) United States
(12) Patent Application Publication
(10) Pub. No.: US 2026/0181811 A1
(43) Pub. Date: Jun. 25, 2026

(54) MODULE CAGE HAVING CABLE MANAGEMENT AND DUCTS

(71) Applicant: HEWLETT PACKARD ENTERPRISE DEVELOPMENT LP, Spring, TX (US)

(72) Inventors: Paul Wesley Stelter, San Bruno, CA (US); Vance Brey Murakami, Los Gatos, CA (US); Harold Zin Htutt, Fremont, CA (US)

(21) Appl. No.: 18/999,364

(22) Filed: Dec. 23, 2024

(51) Int. Cl. H05K 7/14; H05K 7/20

(52) U.S. Cl. CPC H05K 7/1491; H05K 7/20727

(57) ABSTRACT

An information processing system includes a chassis and a system board supported by the chassis and having a processor. The chassis further supports a plurality of fans. A cage having a front bracket and a pair of side brackets is coupled to either the system board or the chassis, with the cage defining at least two bays to receive pluggable modules. The front bracket further includes at least one pair of cable management supports extending forward from the front bracket. At least two cables each comprising a first cable connector are coupled to the front bracket and arranged to mate with the pluggable modules. Each pair of the cable management supports is arranged to support a flexible wire portion of one of the cables at a location forward of the front bracket and hold the flexible wire portion at a position higher than an airflow opening in the front bracket.

Information processing systems, such as servers and networking devices, often have one or more system boards (e.g., motherboards), peripheral components connected to the system board(s), and a chassis to support and house the various components. In some systems, some of the peripheral components are selectively coupled to the system board using cables, with a cable extending from the particular component and coupling to a corresponding receptacle on the primary system board. The components of the system, including peripheral components, may be cooled by fans disposed in the chassis.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a module cage having cable management and ducts.

FIG. 2 is a rear perspective view of a module cage having cable management and ducts with one pluggable module installed.

FIG. 3 is a rear perspective view of the module cage of FIG. 2 with a second pluggable module installed.

FIG. 4 is a front perspective view of a module cage having cable management and ducts with two pluggable modules installed.

FIG. 5 is a top view of a module cage having cable management and ducts.

FIG. 6 is a side elevation view of a module cage having cable management and ducts.

FIG. 7 is a front perspective view of the module cage of FIG. 4 in a state of having two cables coupled to the modules.

FIG. 8 is a rear perspective view of the module cage of FIG. 7.

FIG. 9 is a side elevation view of the module cage of FIG. 7.

FIG. 10 is an example method for installing a module in an information processing system having a module cage having cable management and ducts.

### DETAILED DESCRIPTION

In many servers, pluggable modules are installed in the system to provide various functionalities to the server. For example, a host bus adapter (HBA) module may be installed within a server to connect the server with storage devices, which may be a peripheral device such as a storage array, as well as with other network adapters. In servers using pluggable modules, the modules may be installed within a module bay disposed as part of the system. The module bay may be formed as part of a cage such that a pluggable module is able to be received in the bay and be supported by the cage. Various cages may be disposed in the system to receive different types of pluggable modules, and each cage may have one or more module bays.

The primary system board is often disposed in the middle area of the chassis and may be fixedly mounted to the chassis in this position. The cage may then be coupled to either the primary system board or the chassis, depending on the design of the server system. Fans of the system are generally arranged linearly on the chassis, either in front of or behind the primary system board, to provide airflow over the system board, including over any pluggable modules which may be installed within the system at a given time.

In some instances, a pluggable module may be coupled to the system board using a cable. More particularly, a first cable connector may be coupled to the cage such that, when a pluggable module is installed within a bay of the cage, the pluggable module blind mates with the cable connector. A flexible wire portion of the cable may extend from the first cable connector and terminate at a second cable connector coupled to the system board.

One challenge of using cables to couple peripheral modules, including pluggable modules, to a system board is that the cables can block airflow to the modules, hampering their cooling. This issue may be particularly acute with pluggable modules due to the cage, as the cage itself may present an obstacle to getting airflow to the modules. While openings may be provided within the cage to allow some airflow, cables sometimes partially or fully block at least some of these openings, resulting in a reduction in the amount of air received by the modules.

In addition, cables often move within the system over time, even with proper initial routing. For example, cables that are initially routed so as not to obstruct airflow openings in a module cage may drop or move from a routed position to a position in which the cable partially or fully blocks the airflow opening. This cable movement may occur, for instance, with a cage designed to receive more than one module in a stacked arrangement, with a cable from an upper module moving down over time (e.g., due to gravity) to block an airflow opening designed to provide airflow across a lower module. As a result, it can be challenging to adequately cool pluggable modules in systems where the pluggable modules are coupled to the system board by cables.

To address these and other issues, examples disclosed herein include systems including cages designed to receive pluggable modules, such as HBAs, which have both cable management and additional cooling features integrated into the cage. More particularly, example cages disclosed herein comprise two side brackets and a front bracket, with an open rear end opposite the front bracket to receive a module. Multiple cable connectors are mounted to the front bracket in a vertically stacked manner to mate with modules installed in vertically stacked bays in the cage. In other words, for each bay in the cage, a corresponding cable connector of a cable may be arranged on the front bracket in alignment with the bay. The front bracket has one or more airflow openings, including a central airflow opening disposed between an adjacent pair of the cable connectors, to allow airflow into the cage. The front bracket also includes at least one set of cable management supports which extend from the front wall in a forward direction, with each set of cable management supports being configured to support the flexible wire portion of one of the cables at a location forward of the connectors, thus preventing the flexible wire portion from drooping down over time and blocking one of the airflow openings. Thus, adequate airflow to the modules in the cage may be ensured.

The front bracket may include a top wall, a bottom wall, and two side walls extending perpendicular to and connecting the top wall and the bottom wall. The top, bottom, and side walls may define a central opening therein, which may permit airflow through the front bracket of the cage. As noted above, the front bracket includes at least one pair of cable management supports coupled thereto. The cable management supports may extend away from the front face of the bracket in a forward direction (i.e., away from a module installed in the cage). The cable management supports may be coupled to the side walls of the front bracket, with one cable management support of the pair located on each of the side walls and separated by the central opening of the front bracket.

When a module is installed in the cage, a cable may be used to couple the module to a system board, as noted above. In some examples, the cable may be routed over the pair of cable management supports such that the cable management supports support and maintain the cable in an elevated position relative to the system board. This routing may aid in keeping the central opening of the front bracket free from obstruction, particularly from obstruction resulting from a fallen or drooping cable.

In some examples, the cage may include a second pair of cable management supports coupled to the front bracket thereof. The second pair of cable management supports may be located below the first pair of cable management supports and may similarly extend away from the front bracket of the cage in a forward direction, with the second pair of cable management supports being parallel to the first pair of cable management supports. As with the first pair of cable management supports, the second pair of cable management supports may comprise one support on each of the side walls such that the pair of cable management supports are separated by the central opening.

In some examples, the side brackets of the cage may include a plurality of guide rails disposed on an interior surface thereof, with the guide rails facing towards the interior of the bays defined in the cage. The guide rails may be configured in pairs; that is, two guide rails may be disposed opposite one another, with one on each side bracket, to receive and guide a module as it is being inserted into the cage. In some examples, the guide rails may include additional features that provide rough alignment of a module as the module is inserted into the cage. For example, the guide rails may include chamfers and/or rounded edges at the ends thereof, although examples are not so limited and other alignment features may be present. In some examples, the guide rails may support the module once the module is installed in the cage. Each guide rail may include an upper wall and a lower wall with a recess defined between the upper wall and lower wall; the module is designed to be received in the recess of the guide rails, with the upper and lower walls preventing vertical movement of the module. In this manner, the module is slidably engageable with the guide rails. Once the module reaches the front face of the cage, i.e., is slid the length of the guide rails, the module may then be mated via blind mating to a receptacle on the cage, with the receptacle including one of the cable connectors.

In some examples, each side bracket may further include at least one duct defined therein. As used herein, a duct refers to an opening configured to receive and direct airflow. In some examples, a duct may include a protrusion extending from an end of the duct, with the protrusion designed to aid in directing airflow in a specific desired direction. In other examples, a baffle may be coupled to the side bracket adjacent to at least one duct, with the baffle also designed to aid in directing airflow in a specific desired direction. Each side bracket may have at least one duct extending through a thickness of the side bracket material and the protrusion or baffle extending outwardly and away from an outer surface of the side bracket, opposite the guide rail. In some examples, a plurality of ducts may be used, with each duct disposed linearly along a length of a respective side bracket of the cage. In other examples, a single duct may be used. In such examples, the single duct may extend substantially entirely along a length of the respective side bracket. In either example, the ducts may be formed in a side wall of the side bracket, with the side wall being a flat, planar portion disposed above and below the various guide rails.

In some examples with ducts, each duct may have a protrusion or flap extending from an end of the duct. The flap may extend angularly out from an end of the duct and may be angled to direct airflow. In other examples, a baffle may couple to the side bracket and extend angularly out from an end of the duct to direct airflow. In some examples, the angle of the flap or baffle may be selected to maximize airflow through the ducts and thus over the components installed within the cage. That is, air may be pulled into the center of the cage, over the module installed therein, at the side ducts to increase the amount of air moved over at least a portion of the module or modules installed within the cage. As a result, the modules may be cooled more effectively and efficiently, and air that would otherwise have less contact with a component of the system is able to provide additional cooling where it is most advantageous in the system. The flaps and the baffles may serve similar purposes but may differ from one another in a few ways, particularly in that the flaps are provided on a per-duct basis (one flap per duct) while the baffles may be provided for groups of ducts (e.g., one baffle for all of the ducts on a given side bracket). Thus, in some cases, the flaps may be smaller (in surface area) than the baffles. In some examples, the flaps can be formed integrally with the side bracket as part of forming the duct, for example by cutting the side bracket on three sides of the duct opening and bending out the remaining material formerly covering the duct opening to form the flap.

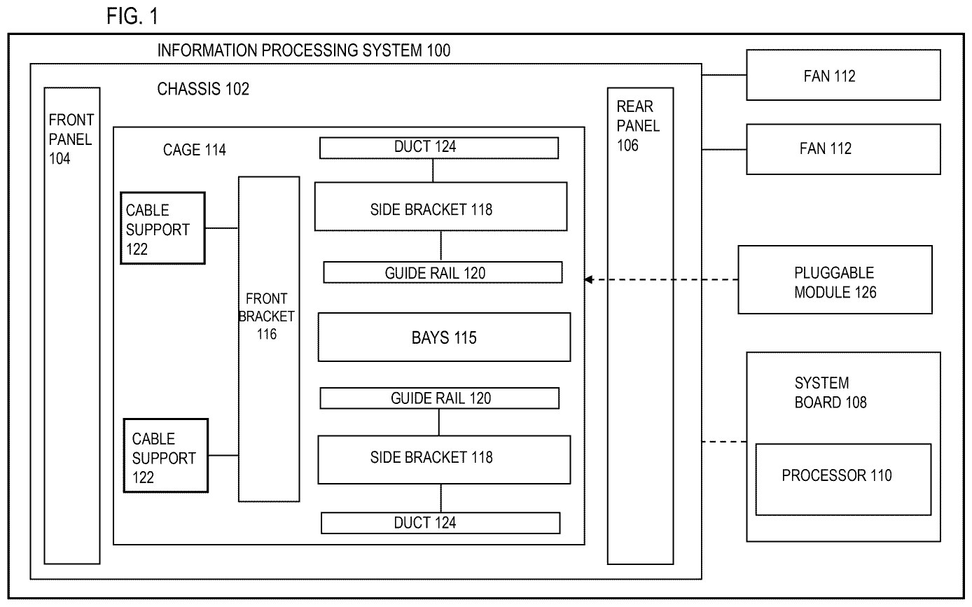

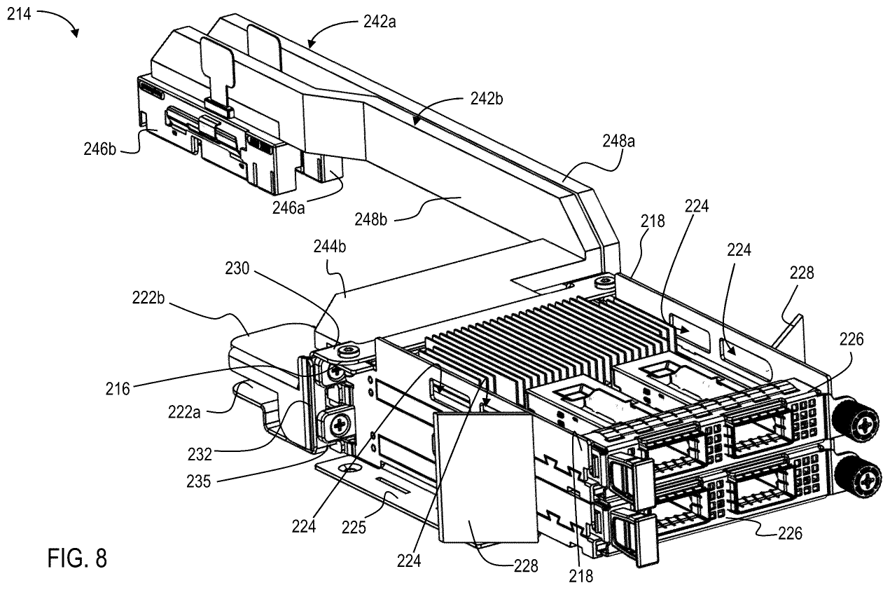

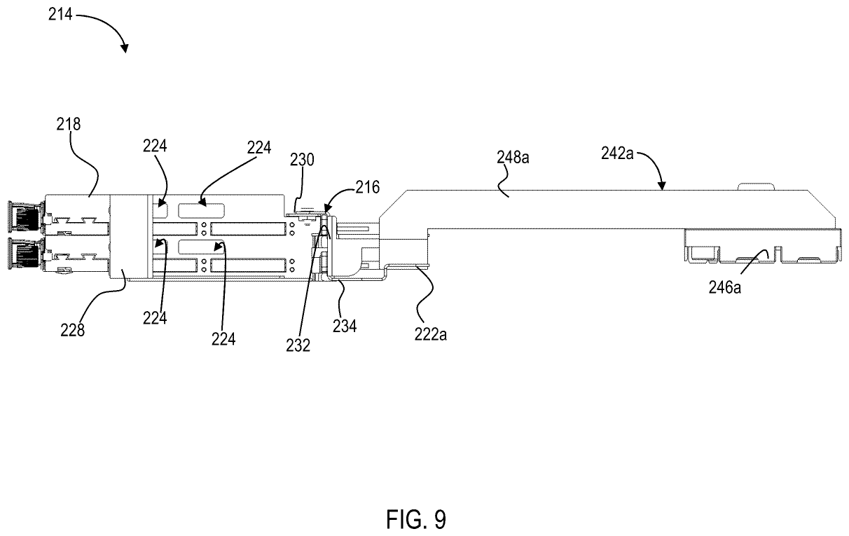

These and other examples will be described in greater detail below in relation to FIGS. 1-10.

FIG. 1 illustrates an example information processing system 100. FIG. 1 is schematic in nature, and it should be understood that FIG. 1 is not intended to illustrate specific shapes, dimensions, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Furthermore, connections which may be intermittent or conditional (e.g., occurring in some states but not in others) are indicated by dashed-line arrows.

Information processing system includes a chassis 102 which physically supports, and in some cases encloses or houses, the other components of the system 100. The chassis 102 may include a front panel 104 and a rear panel 106, as well as other structural members (not illustrated) such as a base, side walls, a cover, etc.

A system board 108 may be supported by the chassis 102. The system board 108 includes a printed circuit board (PCB) (not illustrated), and various components mounted to the PCB, including at least a processor 110. The system board may also include additional components mounted to the PCB, such as memory modules, power delivery components, etc., which are familiar to those of ordinary skill in the art and thus are not described in detail herein. The system board 108 may be a motherboard, a host processor module (HPM) board, or any other suitable board.

The system board 108 also includes at least one system board connector (not illustrated in FIG. 1), which may be coupled to the PCB of the system board 108. A system board connector refers to a connector at which a component may be connected, either selectively or permanently, with the system board. In system 100, the system board connector may be configured to allow a pluggable module such as pluggable module 126 to be coupled with the system board 108 when the pluggable module 126 is installed within the system 100, as is described further herein.

The chassis 102 may further support a plurality of fans 112. More particularly, the plurality of fans 112 may be coupled to the chassis 102 along a width of the chassis 102 and may be disposed substantially parallel to the front panel 104 and/or the back panel 106, although examples are not so limited. The fans 112 may further be coupled to system board 108 at fan connectors (not shown) such that fans 112 are able to receive power and provide cooling to the components of the information processing system 100.

Information processing system 100 may further include a cage 114. Cage 114 may be coupled to the chassis 102 or to the system board 108. As described previously, cage 114 may be configured to receive a pluggable module, such as pluggable module 126, within a bay 115 defined within the cage 114. More particularly, cage 114 may include a front bracket 116 and two side brackets 118 coupled to front bracket 116 and extending perpendicularly therefrom, with side brackets 118 being disposed substantially parallel to one another. The front bracket 116 and side brackets 118 define a volume therebetween, referred to herein as an internal volume of the cage 114, which may be further divided into one or more sections or sub-volumes configured to receive a pluggable module such as pluggable module 126. Each bay 115 may include one of these sections or sub-volumes the interior volume of the cage 114 and also the portions of the front bracket 116 and the side brackets 118 which bound and define that section/sub-volume. In other words, each bay 115 corresponds to a portion of the cage 114 which receives one pluggable module 126.

Side brackets 118 may include guide rails 120, with at least one guide rail 120 coupled to each side bracket 118. The guide rails 120 may be disposed generally parallel to one another on an inner portion of the side brackets 118 such that the guide rails 120 face the bay defined in the cage 114. Pluggable module 126 may interface with guide rails 120 when pluggable module 126 is inserted into a bay defined in cage 114 such that guide rails 120 aid in positioning and supporting the pluggable module 126 within the cage 114.

The pluggable module 126 may be coupled to the system board 108 by a cable (not shown in FIG. 1). More particularly, at least two cables may be coupled to the front bracket 116 of cage 114. Each cable comprises a first cable connector coupled to the front bracket 116 of the cage 114 such that the first cable connector is configured to mate with the pluggable module 126 when pluggable module 126 is installed within a bay of cage 114. A second cable connector may be coupled to the system board 108 to allow pluggable module 126 to receive power. The first and second cable connectors are separated by a flexible wire portion of the cable.

The front bracket 116 may further comprise at least one pair of cable management supports 122. Each cable management support 122 may extend forward from the front bracket 116. In some examples, cable management supports 122 may be integrally formed with front bracket 116; for example, the cage 114 may be formed from a continuous piece of sheet metal and cable management supports 122 may be formed from the same piece of sheet metal such that cable management supports 122 are integral to the front bracket 116. In other examples, cable management supports 122 may be formed as a separate component and attached the front bracket 116 via, e.g., welding, adhesive, etc.

The cable management supports 122 may be configured to support the flexible wire portion of a cable used to couple the pluggable module 126 to the system board 108. More particularly, the cable management supports 122 may support the flexible wire portion of the cable at a location that is forward of the front bracket 116. In addition, the cable management supports 122 may elevate or otherwise hold the flexible wire portion of the cable at a location that is higher than an airflow opening in the front bracket 116 to maintain airflow through the information processing system 100.

Airflow through the information processing system 100 may further be directed and aided by ducts 124 formed in side brackets 118. More particularly, each side bracket 118 may have at least one duct 124 formed therein. Each duct 124 may include a cutout extending through the side bracket 118. The ducts 124 may be configured to draw in air, such as air from fans 112, through their respective cutouts to allow the air to move over the pluggable module 126 when the pluggable module 126 is installed in the cage 114. In some examples, the ducts 124 may include additional air-directing features, such as flaps or baffles, to further assist in directing airflow through the ducts 124 and over the pluggable module 126.

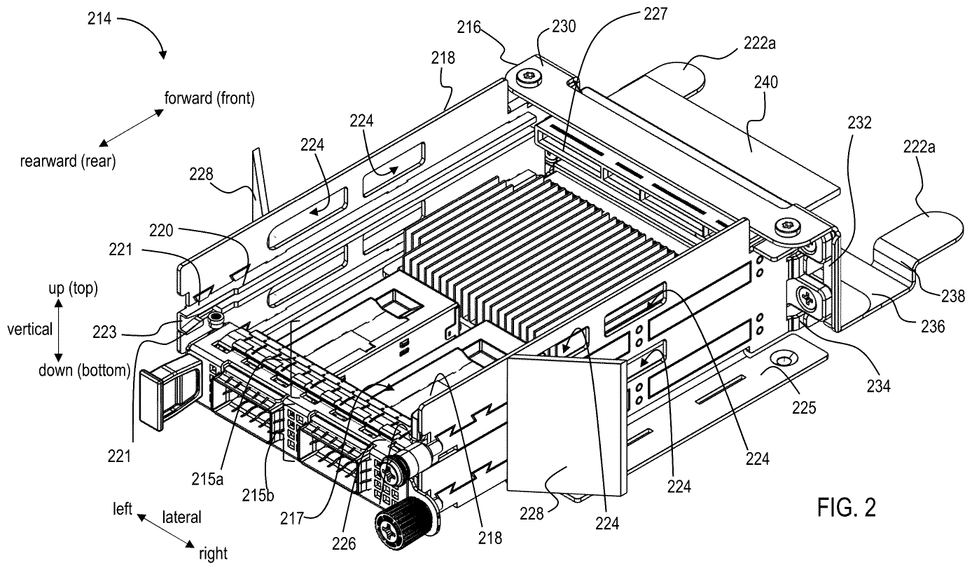

Turning now to FIGS. 2-9, an example of a cage 214 that could be used in an information processing system such as system 100. Cage 214 may be one implementation example of cage 114 shown in and described with respect to FIG. 1 and may be used in a system such as system 100, described with respect to FIG. 1. Cage 214 thus comprises components which correspond to (i.e., are implementation examples of) components of the cage 214, and the correspondence between such components is indicated herein by the components having reference numbers with the same last two digits, such as 126 and 226. Aspects of the cage 114 and its components described above may also be applicable to the cage 214 and its corresponding components, but the cage 114 and its components are not limited to the cage 214 and its components, which are just one example of how the cage 114 may be implemented. In some instances, aspects of the cage 114 already described above, which are also applicable to the cage 214, are not described below to avoid duplicative description.

Herein, reference is made to various directional or spatial-relational terms, such as forward, rearward, lateral (or side), vertical, etc. These directional terms are to be understood relative to a reference frame fixed to the cage 215 as illustrated in the Figures (see, e.g., FIG. 2), but are not intended to limit the position or orientation of the cage 214 relative to an external reference frame. Thus, for example, the term vertical or related terms (e.g., up, down, above, below, top, bottom, etc.) relates to a dimension of the cage 215 as shown in FIG. 2 but does not limit the orientation of the cage 214 relative to the ground (e.g., the “vertical” direction could be parallel to the ground if the cage 214 is so oriented). As another example, the term “forward” or related terms refers to a direction of insertion of pluggable modules into the cage 214 but does not limit the orientation of the cage 214 within a system chassis. The term “horizontal” refers to any direction perpendicular to the vertical, which includes lateral directions and forward/rearward directions as shown in FIG. 2. In some examples, when the cage 214 is installed in a system, the vertical dimension is perpendicular to the system board of the system.

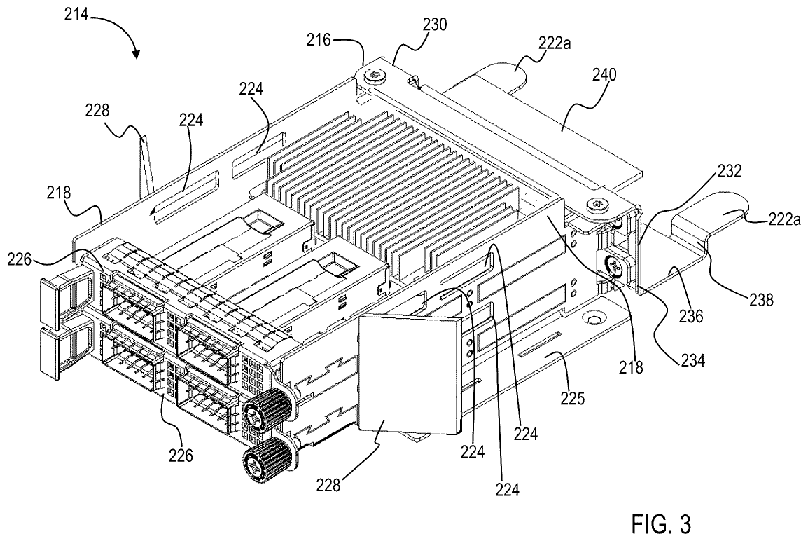

Cage 214 includes a front bracket 216 and a pair of side brackets 218 extending perpendicularly rearward from the front bracket 216. At least two bays 215 may be defined by the front bracket 216 and the pair of side brackets 218, with each bay configured to removably receive a pluggable module such as module 226. In the implementation illustrated in FIG. 2, the cage 214 has two bays 215 including an upper bay 215a and a lower bay 215b, and FIG. 2 shows the cage 214 in a state in which a single module 226 has been installed in the lower bay 215b while the upper bay 215a is open for receiving a second module 226. Each bay 215 comprises a portion of the interior volume 217 defined between the front bracket 216 and the side brackets 218, as well as portions of the front bracket 216 and the side brackets 218 which bound that portion of the volume 217. FIG. 3 shows the same cage 214 in a state in which two modules 226 are installed. Although the illustrated cage 214 comprises two bays 215, it should be understood that in other examples (not illustrated) more than two bays 215 may be present, and one of ordinary skill in the art would understand, after reading this disclosure, how to apply the principles disclosed herein in relation to the two-bay cage 214 to the other examples with more than two bays 215. Portions of the cage 214 may be formed from sheet metal which has been stamped or otherwise worked to form the structures disclosed herein. In particular, each of the side brackets 218 and the front bracket 216 may be formed from sheet metal pieces which are joined together (e.g., via fasteners).

The pair of side brackets 218 may include a pair of guide rails 220 disposed along an inner surface of the pair of side brackets 218. Although only one guide rail 220 is shown in FIG. 2, it is to be understood that each side bracket 218 has guide rails 220, with the pair of guide rails 220 being parallel to one another. In addition, each side bracket 218 may have multiple guide rails 220 such that cage 214 has multiple pairs of guide rails 220. In such examples, the guide rails 220 may be offset from one another, i.e., a first pair of guide rails 220 may be disposed at a first location on the side brackets 218 and a second pair of guide rails 220 may be disposed at a second location on the side brackets 218. In some examples, the number of pairs of guide rails 220 may correspond to the number of bays defined in the cage 214. Guide rails 220 may formed from overmolded plastic, which may be coupled to the sheet metal of the cage 214.

Each guide rail 220 may include a pair of ledges 221 extending parallel to one another and defining an opening 223 therebetween. The ledges 221 may be sized to receive a module 226 therein, with the edges of the module 226 engaging with the ledges 221 to guide and support the module 226 as it is inserted into cage 214. A sidewall of module 226 may be received within the opening 223, such that the module 226 is bounded on an upper surface and a lower surface by ledges 221. In this manner, when module 226 is inserted into cage 214, the pair of guide rails 220 receive and guide the module 226 along the length of the cage 214 to assist in positioning the module 226 with respect to the cage 214 and thus with respect to a cable coupled to the cage at a front bracket 216 thereof.

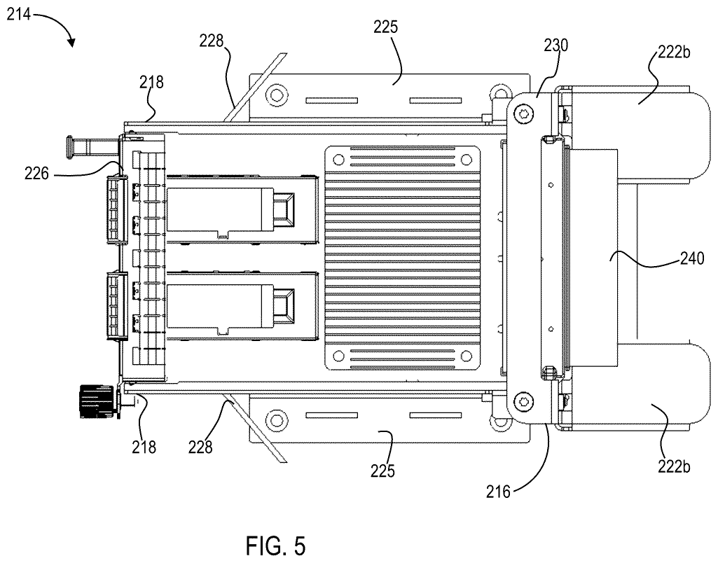

Each side bracket 218 of the pair of side brackets 218 may further include a ledge 225 extending from a lower portion of the side bracket 218. As shown in FIG. 5, each side bracket 218 has a corresponding ledge 225. Ledges 225 extend away from side brackets 218 such that ledges 225 are substantially perpendicular with the side brackets 218. Ledges 225 may serve as points of connection between the cage 214 and a chassis. As such, ledges 225 may include openings to receive screws or other fasteners to facilitate such connection.

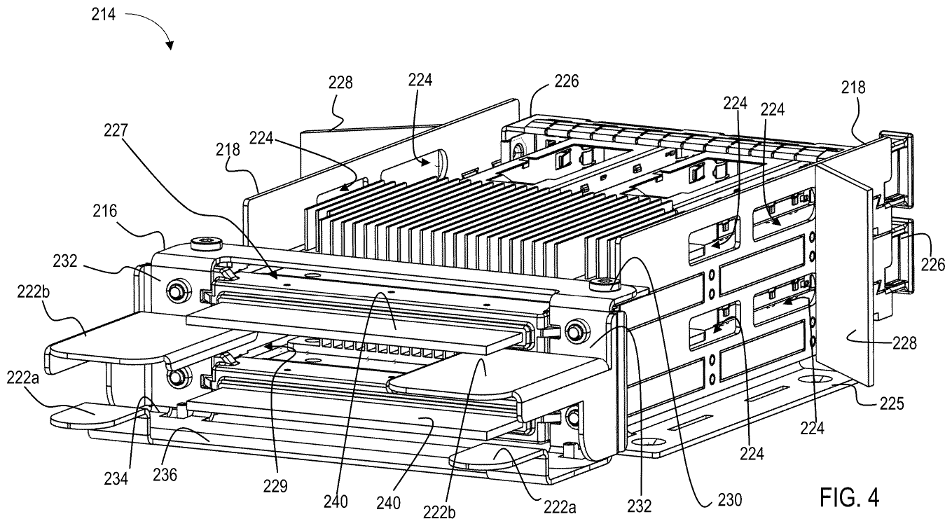

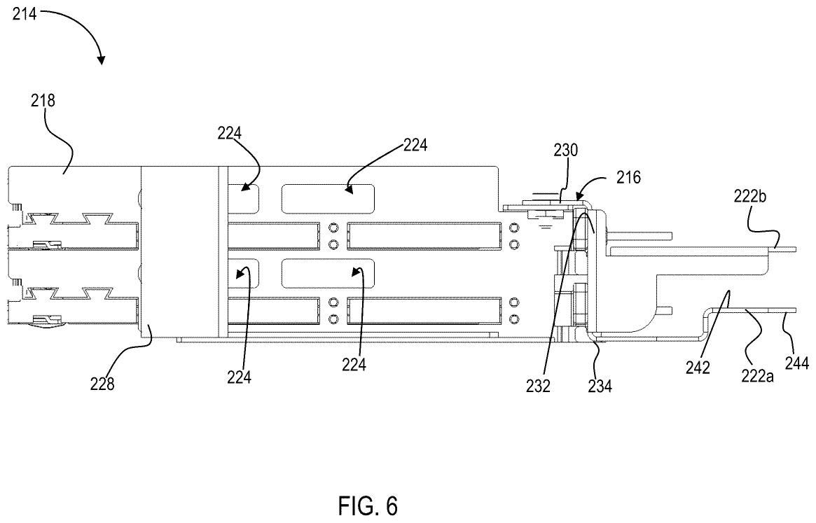

A plurality of ducts 224 may be disposed in the pair of side brackets 218. Although four ducts 224 are shown in a side bracket 218 in, e.g., FIGS. 4 and 6, examples are not so limited and other numbers of ducts 224 may be used. In addition, it is to be understood that the configuration of the ducts 224 is not limited to the examples shown in FIGS. 2-9. For example, ducts 224 may be disposed at different locations along the side bracket 218, with the locations being determined in view of cooling considerations for the cage 214 and for the system in which cage 214 is disposed.

Each duct 224 includes a cutout disposed through its respective side bracket 218 such that air is able to flow through the side brackets 218 and over modules 226 installed in the cage 214. To aid and direct airflow through the ducts 224, baffles 228 may be coupled to side brackets 218. As used herein, a baffle refers to a panel that can be used to direct airflow. As shown particularly in FIGS. 2-4, baffles 228 may be generally planar. Each baffle 228 may be coupled with a respective side bracket 218 such that the baffle 228 extends at an angle away from the side bracket 218, as shown in FIG. 5. The particular angle of the baffle 228 may be selected and/or adjusted based on desired airflow direction. Although one baffle 228 is shown on each of side bracket 218, examples are not so limited and other numbers and/or configurations of baffles may be used. For example, a smaller baffle may be coupled to the side bracket 218 adjacent to each individual duct 224 to provide airflow direction through each duct 224 individually.

Front bracket 216 includes a top wall 230, a bottom wall 234, and a pair of side walls 232 connecting the top wall 230 and the bottom wall 234. A central opening 227 is defined therein. A ledge 236 may extend forward from bottom wall 234. The ledge 236 may have an integrally formed pair of cable management brackets 222. More particularly, as shown in, e.g., FIGS. 2-3, ledge 236 may have a bent portion 238 that extends perpendicularly upward from ledge 236. A first pair of cable management brackets 222a extends forward from the bent portion 238, with the cable management bracket 222a being generally parallel to the ledge 236. Thus, cable management brackets 222a extend forward from the front bracket 216 in a direction opposite the opening defined in the 214 by the front bracket 216 and the pair of side brackets 218.

Each bracket of cable management brackets 222a may be coupled to a respective side wall 232 of the front bracket 216 such that cable management brackets 222a are separated by the central opening 227. As a result, central opening 227 remains unobstructed by the cable management brackets 222a; that is, cable management brackets 222a do not obstruct airflow through the central opening 227.

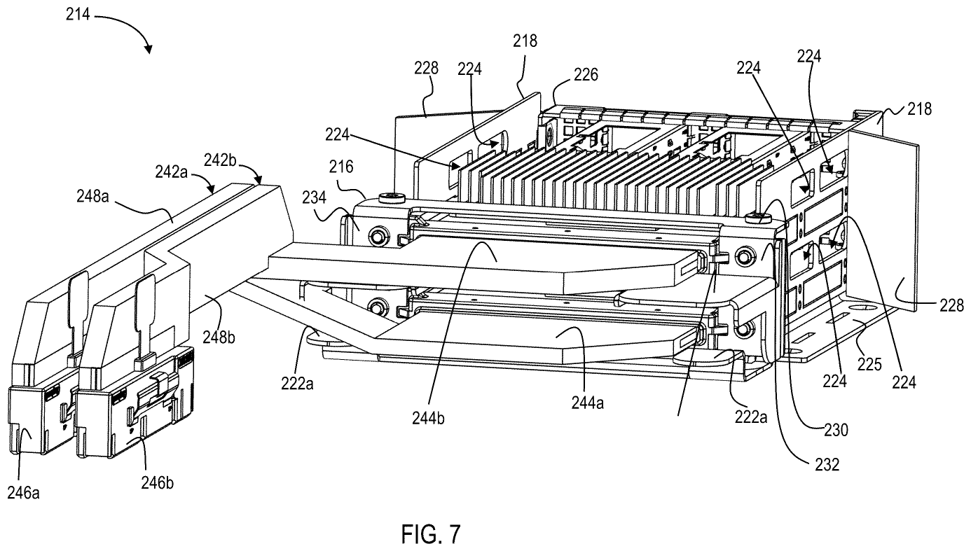

As shown in FIG. 6, each bracket 222a includes top surface 242 and a bottom surface 244, with the bottom surface 244 disposed opposite the top surface 242. In use, the top surface 242 may support a cable, as shown in FIGS. 7-9. Similarly, each bracket 222b includes an upper surface and a lower surface (not labeled in FIG. 6) such that a cable is supported by the bracket 222b at the top surface.

A second pair of cable management supports 222b may extend forward from the front bracket 216. More particularly, the second pair of cable management supports 222b extend from the front bracket 216 parallel to the first pair of cable management supports 222a. In addition, the second pair of cable management supports 222b may be offset from the first pair of cable management supports 222a, as shown in FIG. 4. The inclusion of a second pair of cable management supports 222b results in central opening 227 being split, with an opening 229 being defined between the first pair of cable management supports 222a and the second pair of cable management supports 222b. Opening 229 may correspond to a lower module 226; that is, opening 229 may be located such that a module 226 installed in a lower bay of cage 214 is aligned with the opening 229. A portion of central opening 227 may extend above the second pair of cable management supports 222b and be aligned with an upper bay of cage 214.

Similarly to first pair of cable management supports 222a, second pair of cable management supports 222b may be coupled to a respective sidewall 232 of the front bracket 216 such that cable management supports 222b are separated by the central opening 227. This may allow central opening 227, as well as opening 229, to remain unobstructed by cable management supports 222b. As a result, air can flow through front bracket 216 into cage 214 and over any modules 226 installed therein.

A second set of ledges 240 may be coupled to front bracket 216. As shown in FIG. 4, ledges 240 may be coupled to or integrally formed with front bracket 216 and may extend forward therefrom, parallel to first pair of cable management supports 222a and second pair of cable management supports 222b. Ledges 240 may provide another point of contact for a cable such as cables 242a, 242ab shown in FIGS. 7-9. For example, as seen in FIG. 7, a portion of cable 242a is supported by first cable management supports 222a and a portion of cable 242b is support by second cable management supports 222b, while another portion of cables 242a. 242b are supported by corresponding ledges 240. This may provide additional support for cables 242a, 242b and aid in preventing cables 242a, 242b from moving, falling, or drooping such that opening 229 is blocked.

As shown in FIGS. 7-9, each of cables 242a, 242b includes a first cable connector 244a, 244b, respectively, coupled to the front bracket 216, a second cable connector 246a, 246b, respectively, configured to couple with a system board, and a flexible wire portion 248a, 248b, respectively, extending between the first cable connector 244a, 244b and the second cable connector 246a, 246b. It is to be understood that the cables 242a, 242b depicted in FIGS. 7-9 are representative and should not be taken as limiting the physical attributes of such a cable.

More particularly, as shown in FIGS. 7-9, the first cable connector 244a, 244b is coupled to the front bracket 216 such that, when pluggable modules 226 are received within the bays of cage 214, pluggable modules 226 are coupled with the cable 242a, 242b at the first cable connector 244a, 244b. Pluggable modules 226 may mate with respective first cable connectors 244a, 244b by blind mating; that is, when a pluggable module 226 is slidably engaged with the cage 214 at the guide rails 220 and is moved along the length of cage 214, a connector located on the pluggable module 226 that is designed to mate and interface with first cable connector 244a, 244b slides into connection with the first cable connector 244a, 244b As such, first cable connectors 244a, 244b may be coupled with front bracket 216 to align with the location of the bays into which pluggable modules 226 are received within the cage 214.

Once a pluggable module 226 is installed within cage 214 and has interfaced with a respective first cable connector 244a, 244b the flexible wire portion 248a, 248b of cable 248a, 248b may be routed using first cable management supports 222a or second cable management supports 222b. When two modules 226 are installed, as is shown in FIGS. 7-9, two cables 242a, 242b are used and as such, one cable 242a is routed using first cable management supports 222a and the other cable 242a is routed using second cable management supports 222b.

More particularly, a first portion of flexible wire portion 248a of the cable 242a is placed atop a first cable management support of the pair of cable management supports 222a. The cable 242a is then moved across the width of the front bracket 216 to the second cable management support of the pair of cable management supports 222a, where a second portion of the flexible wire portion 248a is placed. In some examples, the cable 242a may be routed over ledge 240 to provide additional spacing from the central opening 227.

A similar process occurs with respect to the second cable 242b As with the first cable 242a a first portion of the flexible wire portion 248b of the cable 242b is placed on a first cable management support of the pair of cable management supports 222b. A second portion of the flexible wire portion 248b of cable 242b is then placed on the second cable management support of the pair of cable management supports 222b. As with the first cable 242a second cable 242b may be routed over the ledge 240 to provide additional spacing.

Once cables 242a, 242b are routed and placed with respect to the first and second pairs of cable management supports 222a, 222b, the second connectors 246a, 246b may be connected to a system board (not shown in FIGS. 7-9), thus electrically coupling the pluggable module 226 with the system board. By routing the cables 242a, 242b over the cable management supports 222a, 222b, cables 242a, 242b are restricted from moving or drooping into the central opening 227 or into opening 229, thus maintaining airflow through the front bracket 216 of cage 214 so that air flows over modules 226.

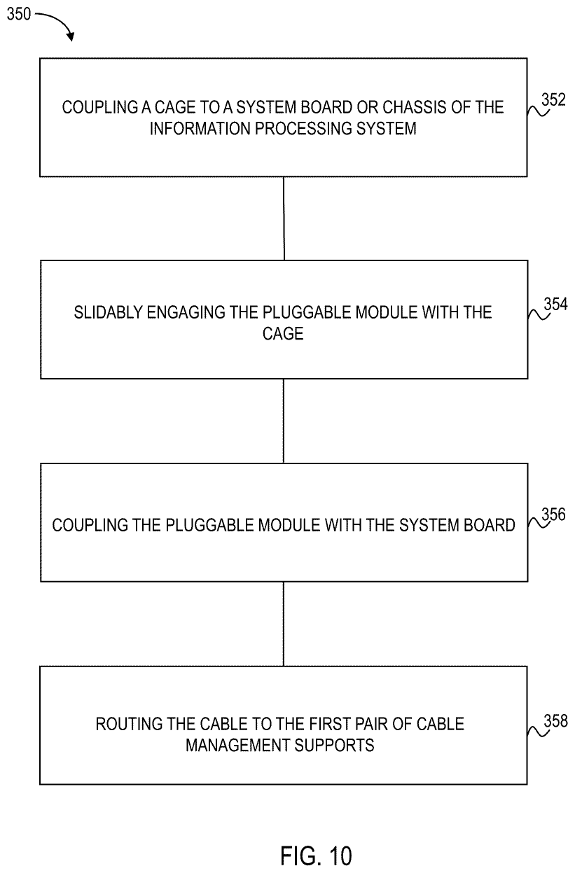

FIG. 10 is an example method 350 for installing a module in an information processing system having a module cage having cable management and ducts. At 352, method 350 includes coupling a cage to a system board or chassis of the information processing system. As described previously with respect to FIGS. 2-9, the cage may include a front bracket and a pair of side brackets, with the pair of side brackets extending perpendicular from the front face to define at least two bays to removably receive pluggable modules. The cage may be coupled to the system board or chassis at ledges extending perpendicular from the pair of side brackets, as discussed with respect to FIGS. 2-5, although examples are not so limited, and the cage may be coupled at other locations.

The cage coupled to the system board or chassis at 352 further includes a first pair of cable management supports which may be integrally formed with the front bracket of the cage. The cable management supports may extend perpendicular from the front face of the bracket, as described with respect to FIGS. 2-6. More particularly, the first pair of cable management supports may be each be coupled with a respective side wall of the front bracket.

In some examples, the cage coupled to the system board or chassis at 352 may include a second pair of cable management supports offset from the first pair of cable management supports. The second pair of cable management supports may similarly extend perpendicular from the front face of the bracket, as described with respect to FIGS. 4-5.

The cage may further include a first pair of guide rails coupled to the side brackets and facing the bays defined by the front bracket and the pair of side brackets. A second pair of guide rails may further be disposed offset from, but parallel to, the first set of guide rails, such that more than one pluggable module may be installed in the cage. In addition, the cage may further include a first pair of ducts formed within the pair of side brackets. As discussed with respect to FIGS. 7-9, the ducts may be formed within the side brackets to allow airflow through the side brackets and over a pluggable module installed within the cage.

At 354 method 350 includes slidably engaging the pluggable module with the cage. More particularly, the pluggable module is engaged with the first pair of guide rails, as described with respect to FIG. 2. Once engaged, the pluggable module is moved along a length of the cage, and along the length of the guide rails, until a front edge of the pluggable module is adjacent to the front bracket of the cage. In addition, when the pluggable module is slidably engaged with the cage, the first pair of ducts will be parallel to the sides of the pluggable module, allowing the top face of the pluggable module to be exposed to airflow through the ducts.

At 356, method 350 includes coupling the pluggable module with the system board by a cable. The cable may be coupled to the front bracket, as described with respect to FIGS. 7-9, such that a first connector of the cable is configured to blind mate with a corresponding receptacle on the pluggable module. A second connector of the cable, disposed apart from the first connector but connected thereto by a flexible wire portion, may be coupled to the system board of the information processing system. In this way, when the pluggable module engages with the first connector, the cable electrically couples the pluggable module to the system board.

At 358, method 350 includes routing the cable to the first pair of cable management supports. More particularly, and as described with respect to FIGS. 7-9, the flexible wire portion of the cable may be routed over the cable management supports to aid in positioning the flexible wire portion such that it does not block airflow through the front bracket of the cage. Routing the cable may first comprise placing a first flexible wire portion of the cable atop a first cable management support of the pair of cable management supports. Then, a second flexible wire portion of the cable may be placed atop a second cable management support of the pair of cable management supports. As described with respect to FIGS. 7-9, routing the cable in such a manner moves the cable away from the airflow path through the front bracket.

Method 350 may further include slidably engaging a second pluggable module with the cage. The second pluggable module may be engaged at the second pair of guide rails such that the second pluggable module is installed offset but parallel to the first pluggable module. As with the first pluggable module, the second pluggable module may be installed by moving the module along the length of the cage until the second pluggable module reaches the front bracket of the cage. Once the second pluggable module is at the front bracket of the cage, method 350 may include coupling the second pluggable module with the system board by a second cable coupled to the front bracket and configured to mate with the second pluggable module. As with the first pluggable module, the second pluggable module may be configured to blind mate with a first cable connector of the second cable once the second pluggable module is installed within its bay of the cage.

Method 350 may further include routing the second cable to a second pair of cable management supports. Because the second pair of cable management supports are offset from the first pair of cable management supports, the second cable is routed such that it is offset from the first cable. However, the process for routing the second cable is similar to the process for routing the first cable: a first flexible wire portion of the second cable is placed on a first cable management support and a second flexible wire portion of the second cable is placed on a second cable management support. Thus, the second cable is routed to prevent blocking of airflow through the front bracket.

Method 350 may further include adjusting a baffle coupled adjacent to the first pair of ducts to draw air from the information processing system. As described with respect to FIGS. 2-9, the cage may include at least one baffle disposed on each side bracket to assist in drawing in and directing airflow across modules installed within the cage. By adjusting the baffle, adjustments to the airflow drawn from the information processing system can be made. In particular, the baffle may be adjusted to draw air to, and across, the pluggable module when the pluggable module is in a coupled state.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a chassis;
a system board supported by the chassis and having a processor mounted thereto;
a plurality of fans supported by the chassis;
a cage coupled to the system board or the chassis, the cage having a front bracket and a pair of side brackets extending perpendicular from the front bracket and defining at least two bays configured to removably receive pluggable modules, respectively, through an opening in a rear panel of the chassis, wherein the front bracket comprises at least one pair of cable management supports extending forward from the front bracket; and
at least two cables each comprising a first cable connector coupled to the front bracket and arranged to mate with the pluggable modules, respectively, on condition of the pluggable modules being received in the bays;
wherein each pair of the cable management supports is arranged to support a flexible wire portion of one of the cables at a location forward of the front bracket and hold the flexible wire portion at a position higher than an airflow opening in the front bracket.

2. The information processing system of claim 1, further comprising a pluggable module to be received within one of the bays of the cage and to be coupled to one of the first cable connectors to electrically connect the pluggable module to the system board.

3. The information processing system of claim 1, wherein the pair of side brackets further comprise:
a pair of guide rails disposed along an inner surface of the pair of side bracket; and
at least one duct formed within a pair of side walls of the pair of side brackets, the at least one duct further comprising a cutout.

4. The information processing system of claim 3, wherein:
the pair of guide rails are configured to receive and interface with the pluggable module when the pluggable module is received within the cage.

5. The information processing system of claim 3, wherein the at least one duct is configured to draw in air through the cutout and wherein the air is moved over the pluggable module.

6. The information processing system of claim 1, wherein:
the front bracket of the cage further comprises a top wall, a bottom wall, and two side walls connecting the top wall and the bottom wall and defining a central opening therein; and
each cable management support of the pair of cable management supports is coupled to a respective side wall of the two side walls.

7. The information processing system of claim 6, wherein the pair of cable management supports are separated by the central opening of the front bracket.

8. The information processing system of claim 1, wherein:
each cable support of the pair of cable management supports comprises a ledge having a top surface and a bottom surface disposed opposite the top surface;
the ledge extends out from the front bracket of the cage in a direction opposite the opening defined in the cage; and
the ledge is configured to support a cable coupled to the pluggable module and to the connector on the system board when the pluggable module is received within the cage.

9. An information processing system, comprising:
a chassis;
a system board supported by the chassis and having a processor mounted thereto;
a cage coupled to the system board or the chassis, the cage having a front bracket and a pair of side brackets extending perpendicular from the front bracket and defining at least two bays configured to removably receive pluggable modules, respectively, through an opening in a rear panel of the chassis, the cage further comprising:
a first pair of cable management supports integrally formed with the front bracket of the cage and extending forward from the front bracket of the cage;
a first pair of guide rails coupled to the pair of side brackets and facing into the bays defined in the cage, wherein the first pair of guide rails are parallel to one another; and
a first pair of ducts formed within the pair of side brackets, wherein each duct of the first pair of ducts further comprises a first cutout extending through the side bracket; and
at least two cables coupled to the front bracket and arranged to mate with the pluggable modules, respectively, when the pluggable modules are received in the bays, wherein:
each cable is coupled to the front bracket at a first cable connector; and
each cable further comprises a flexible wire portion configured to be supported by the first pair of cable management supports.

10. The information processing system of claim 9, further comprising:
a second pair of cable management supports integrally formed with the front bracket of the cage, wherein:
the second pair of cable management supports extends parallel to the first pair of cable management supports; and
the second pair of cable management supports is offset from the first pair of cable management supports;
a second pair of guide rails coupled to the pair of side brackets and facing into the bays defined in the cage, wherein the second pair of guide rails is offset from the first pair of guide rails;
a second pair of ducts formed within the pair of side brackets, wherein:
each duct of the second pair of ducts further comprises a second cutout extending through the side bracket; and
the second pair of ducts is offset from the first pair of ducts.

11. The information processing system of claim 9, wherein:
the cage and the first pair of cable management supports are formed from a continuous piece of sheet metal; and
the first pair of guide rails is formed from overmolded plastic coupled to the continuous piece of sheet metal.

12. The information processing system of claim 9, wherein:
the front bracket of the cage further comprises a top wall, a bottom wall, and two side walls connecting the top wall and the bottom wall and defining a central opening therein; and
each cable management support of the first pair of cable management supports is integrally formed with a respective side wall of the front bracket of the cage such that the first pair of cable management supports is separated by the central opening.

13. The information processing system of claim 12, wherein the pair of cable management supports maintains the first cable in a desired position such that such that the flexible wire portion is supported at a location forward of the front bracket and higher than an airflow opening in the front bracket.

14. The information processing system of claim 9, further comprising at least one baffle posited adjacent to the first pair of ducts and configured to direct airflow within the information processing system through the first cutout.

15. The information processing system of claim 14, wherein the airflow is directed towards the bays defined in the cage such that the airflow interacts with the first pluggable module when the first pluggable module is received in the cage.

16. A method for installing a pluggable module in an information processing system, comprising:
coupling a cage to a system board or a chassis of the information processing system, wherein the cage further comprises:
a front bracket and a pair of side brackets extending perpendicular from the front face and defining at least two bays to removably receive pluggable modules;
a first pair of cable management supports integrally formed with the front bracket of the cage and extending perpendicularly from the front face of the bracket;
a first pair of guide rails coupled to the pair of side brackets and facing the bays defined in the cage; and
a first pair of ducts formed within the pair of side brackets;
slidably engaging the pluggable module with the cage at the first pair of guide rails;
coupling the pluggable module with the system board by a cable coupled to the front bracket and configured to mate with the pluggable module; and
routing the cable to the first pair of cable management supports.

17. The method of claim 16, wherein slidably engaging the pluggable module with the cage further comprises:
engaging the pluggable module with the first pair of guide rails; and
moving the pluggable module along a length of the cage such that a front edge of the pluggable module is adjacent the front bracket of the cage and first pair of ducts are parallel to the pluggable module.

18. The method of claim 16, wherein routing the cable further to the first pair of cable management supports further comprises:
placing a first flexible wire portion of the cable atop a first cable management support of the pair of cable management supports; and
placing a second flexible wire portion of the cable atop a second cable management support of the pair of cable management supports.

19. The method of claim 16, further comprising:
slidably engaging a second pluggable module with the cage at a second pair of guide rails, wherein the second pair of guide rails is disposed parallel to and offset from the first pair of guide rails;
coupling the second pluggable module with the system board by a second cable coupled to the front bracket and configured to mate with the second pluggable module; and
routing the second cable to a second pair of cable management supports, wherein the second pair of cable management supports are disposed parallel to and offset from the first pair of cable management supports.

20. The method of claim 16, further comprising adjusting a baffle coupled adjacent the first pair of ducts to draw air from the information processing system to the pluggable module when the pluggable module is in a coupled state.
